(19) United States
(12) Patent Application Publication
(10) Pub. No.: US 2005/0289430 A1
(43) Pub. Date: Dec. 29, 2005

(54) Expanding architecture for error correction code and method for the same

(76) Inventors: Bryan Chih-Chen Chen, Hsinchu (TW); Chen Min Chiang, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/873,218

(22) Filed: Jun. 23, 2004

(51) Int. Cl. H03M 13/00

(52) U.S. Cl. 714/752

(57) ABSTRACT

An expanding error correction architecture groups the output data of a data end to several parts, and each grouped output data of the data end is connected to one of a plurality of error correction circuit to be processed for a check sum. One part of the output data of the data end is arranged in a successive form, and another part of the output data of the data end is arrange in a non-successive form. The architecture of the present invention increases the error detection ability for check sums of different data sizes in the data end.

### BACKGROUND OF THE INVENTION

1. Field of the Invention

The present invention relates to an expanding architecture for error correction code and a method for the same, and especially to a data grouping method for testing and verifying the data, respectively.

2. Description of Related Art

Data integrity is a great issue in designing storage media for computers. More particularly, discrepancy between a transmitting end and a receiving end may occur when data transmission is affected by a transmission medium or some external factors.

To check data integrity after a data transmission operation, a parity check procedure can be adopted. For error detection, one parity bit is augmented into one byte or one word of data and the parity of resulting data is checked. Moreover, an error correction code (ECC) can be used to both check and error-correct the data encrypted in this way. Today, error correction code is extensively used in the data structure of memory.

In the ECC procedure, a group of data will be processed to produce a check sum. For example, when processing a data of 256 bytes in ECC procedure, a 3-byte check sum will be produced. When the amount of information data exceeds the load of the ECC procedure, the data is grouped for processing in different batches and check sums are generated one by one. If there are two successive bits in error, the ECC cannot fix them at present.

### SUMMARY OF THE INVENTION

It is an object of the present invention to provide an expanding architecture for error correction code, which can increase the error detection ability and process data of different sizes.

To achieve the object mentioned above, the present invention provides an expanding architecture for error correction code, which comprises a plurality of error correction circuits and a data end with a plurality of output ports, each of the output ports being connected to a corresponding error correction circuit.

To achieve the object mentioned above, the present invention provide an expanding method for error correction code, comprising steps as follows: providing a plurality of data groups from a data end; providing a plurality of error correction circuits; and supplying the plurality of data groups from the data end to one of the error correction circuits.

### BRIEF DESCRIPTION OF THE DRAWINGS

The various objects and advantages of the present invention will be more readily understood from the following detailed description when read in conjunction with the appended drawing, in which:

FIG. 1 shows a block diagram of the first preferred embodiment of the present invention; and

FIG. 2 shows a block diagram of the second preferred embodiment of the present invention.

### DETAILED DESCRIPTION OF PREFERRED EMBODIMENTS

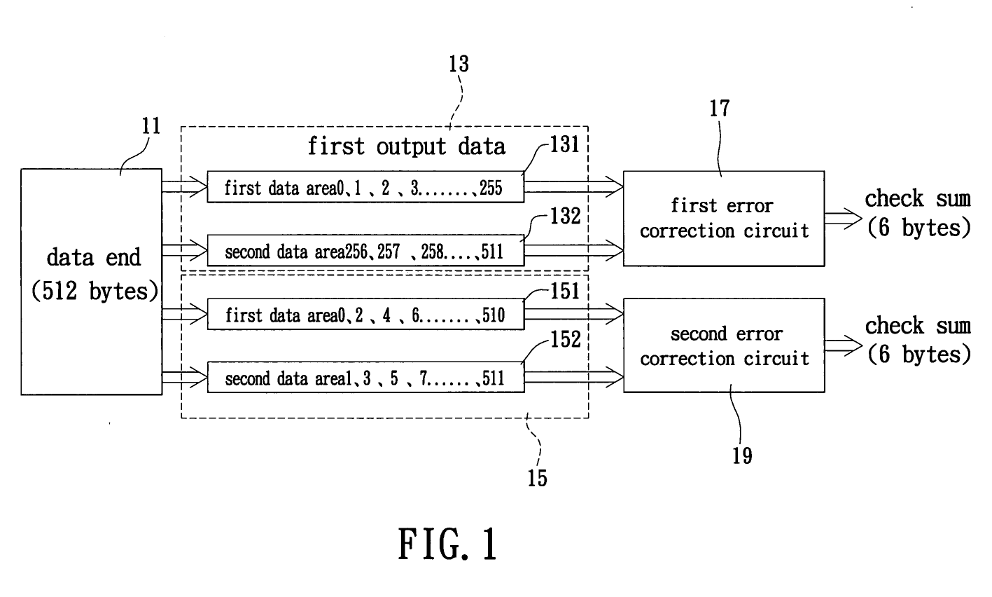

FIG. 1 shows a block diagram of the first preferred embodiment of the present invention. The expanding architecture according to the preferred embodiment comprises a data end 11 and a plurality of error correction circuits 17, 19. The output data of 512 bytes is provided by the data end 11, and the first error correction circuit 17 and the second error correction circuit 19 can process the respective 256 bytes of data to produce a 3-bytes check sum. The output data of the data end 11 is separated into two parts, including a first output data 13 and a second output data 15.

The first output data 13, including the 512 bytes of data from the data end 11, are connected to the first error correction circuit 17. For matching up with the 256 bytes of processing ability of the first error correction circuit 17, the first output data 13 can be partitioned into a first data area 131 and a second data area 132. The first data area 131 includes the 0^{th} byte, 1^{st} byte, 2^{nd} byte . . . to 255^{th} byte of the 512 bytes of data from the data end 11. The second data area 132 includes 256^{th} byte, 257^{th} byte, 258^{th} byte, . . . to 511^{th} byte of the 512 bytes of data from the data end 11.

The second output data 15, including the 512 bytes of data from the data end 11, are connected to the second error correction circuit 19. For matching up with the 256 bytes of processing ability of the second error correction circuit 19, the second output data 15 can be partitioned into a first data area 151 and a second data area 152. The first data area 151 includes the 0^{th} byte, 2^{nd} byte, 4^{th} byte . . . to 510^{th} byte of the 512 bytes of data from the data end 11. The second data area 152 includes 1^{st} byte, 3^{rd} byte, 5^{th} byte, . . . to 511^{th} byte of the 512 bytes of data from the data end 11.

In FIG. 1, the first error correction circuit 17 processes the first data area 131 and the second data area 132 to obtain a 6-byte check sum. The second error correction circuit 19 also obtains a 6-bytes check sum from processing the first data area 151 and the second data area 152. FIG. 1 also shows that the output data sequence is in successive data byte form in the first data end 11, and especially in the first output data 13. In the second output data 15, the output data sequence is in non-successive data byte form, which can been seen from the first data area 151 and the second data area 152.

In the first embodiment, the output data of data end 11 are 512 bytes, but the first error correction circuit 17 and the second error correction circuit 19 process data in 256 bytes. Therefore, the amount of data in data end 11 is greater than the processing ability of the first error correction circuit 17 and the second error correction circuit 19. Therefore, the 512 bytes of data must be separated into 256 bytes of data. For the purpose of the error detection accuracy of the data end 11, the present invention separates the 512-byte data into two 256-byte data groups in the first output data 13, which is in successive data byte sequence, but the second output data 15 is in non-successive data byte sequence. The first error correction circuit 17 and the second error correction circuit 19 will process the check sum of the data end 11 to examine the data accuracy. The architecture of the present invention can process the check sum of data with arbitrary amounts.

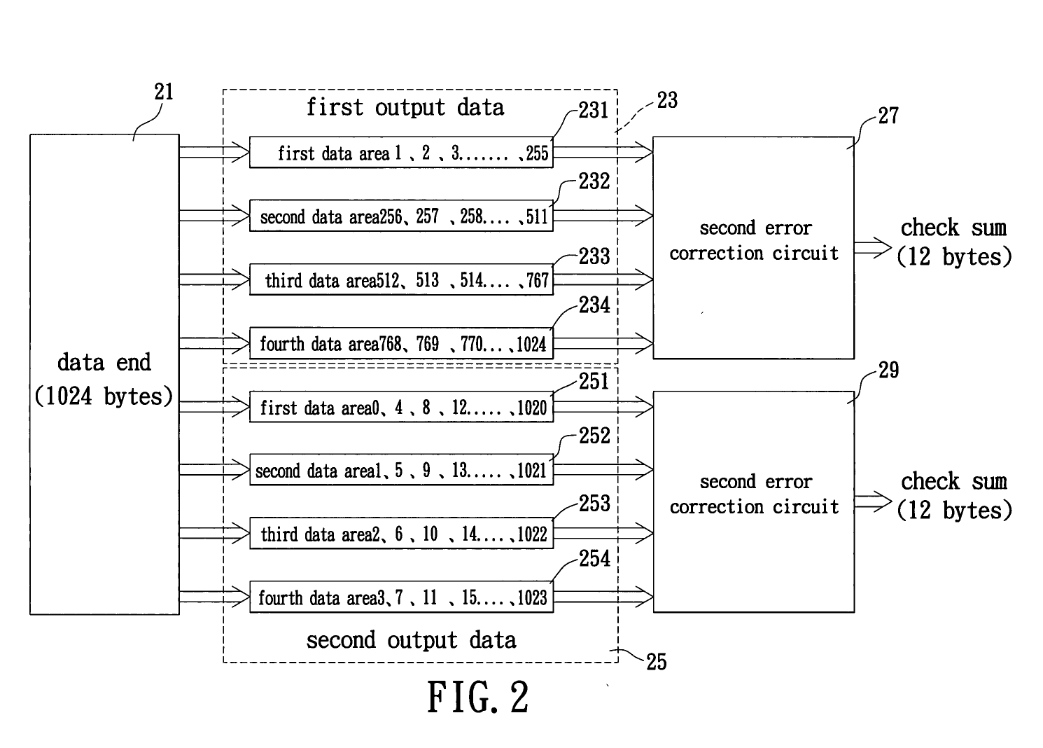

FIG. 2 shows the block diagram of the second embodiment of the present invention. A data end 21 outputs 1024-byte data, while a first error correction circuit 27 and a second error correction circuit 29 only have 256-byte data processing ability to produce a 3-byte check sum. The output data of the data end 21 is also separated into two parts, a first output data 23 and a second output data 25.

The first output data 23, including the 1024-byte data from the data end 21, is connected to the first error correction circuit 27. For matching up with the 256-byte processing ability of the first error correction circuit 27, the first output data 23 can be partitioned into a first data area 231, a second data area 232, a third data area 233 and a fourth data area 234. The first data area 231 includes the 0^{th} byte, 1^{st} byte, 2^{nd} byte . . . to 255^{th} byte of the 1024-byte data from the data end 21. The second data area 232 includes the 256^{th} byte, 257^{th} byte, 258^{th} byte, . . . to 511^{th} byte of the 1024-byte data from the data end 21. The third data area 233 includes 512^{th} byte, 513^{th} byte, 514^{th} byte, . . . to 767^{th} byte of the 1024 bytes of data from the data end 21. The fourth data area 234 includes 768^{th} byte, 769^{th} byte, 770^{th} byte, . . . to 1023^{rd} byte of the 1024-byte data from the data end 21.

The second output data 25, also including the 1024-byte data from the data end 21, is connected to the second error correction circuit 29. For matching up with the 256-byte processing ability of the second error correction circuit 29, the second output data 25 can be partitioned into a first data area 251, a second data area 252, a third data area 253 and a fourth data area 254. The first data area 251 includes the 0^{th} byte, 4^{th} byte, 8^{th} byte, 12^{th} byte . . . to 1020^{th} byte of the 1024-byte data from the data end 21. The second data area 252 includes 1^{st} byte, 5^{th} byte, 9^{th} byte . . . to 1021^{st} byte of the 1024 bytes of data from the data end 21. The third data area 253 includes 2^{nd} byte, 6^{th} byte, 10^{th} byte, . . . to 1022^{nd} byte of the 1024-byte data from the data end 21. The fourth data area 254 includes 3^{rd} byte, 7^{th} byte, 11^{th} byte, . . . to 1023^{rd} byte of the 1024-byte data from the data end 21.

Therefore, with reference also to FIG. 2, the first error correction circuit 27 can process the data in the first data area 231, the second data area 232, the third data area 233 and the fourth data area 234, individually, and obtain a 12-byte check sum. The second error correction circuit 29 also can process the data in the first data area 251, the second data area 252, the third data area 253 and the fourth data area 254, individually, and obtain a 12-byte check sum. Similar to the first embodiment, the second embodiment of the present invention separates the output of the data end 21 into four groups of 256-byte data. FIG. 2 shows that the data in the first data area 231, the second data area 232, the third data area 233 and the fourth data area 234 are in successive data byte sequence; while in the second output data 25, the data are in non-successive data byte form, as can be observed from the first data area 251, the second data area 252, the third data area 253 and the fourth data area 254.

The architecture of the present invention is intended to deal with a large amount of data greater than the capacity of the error correction circuit. The present invention separates the output data into several parts, each part of separated data will be transferred to one of the error correction circuit, and each part of separated data can be arranged in a successive way or in a non-successive way. The data arranged in non-successive data byte form can correct the error in the successive arranged data. By the architecture of the present invention, the data error detection can be more accurate and the correction of the data can be enhanced.

Although the present invention has been described with reference to the preferred embodiments thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the scope of the invention as defined in the appended claims.

1. An expanding architecture for error correction code, comprising:
a plurality of error correction circuits;
a data end with a plurality groups of output data, each output group of the output data being connected to a corresponding error correction circuit.

2. The expanding architecture for error correction code as in claim 1, wherein each output group from the data end is in successive data byte form.

3. The expanding architecture for error correction code as in claim 1, wherein each output group from the data end is in non-successive data byte form.

4. The expanding architecture for error correction code as in claim 1, wherein at least one group of the output data of the data end is in successive data byte form, and other groups of the output data are in non-successive data byte form.

5. The expanding architecture for error correction code as in claim 1, wherein the plurality of error correction circuits, comprising:
a first error correction circuit;
a second error correction circuit.

6. The expanding architecture for error correction code as in claim 5, wherein the data end, having N-bytes output data, wherein the N-bytes output data are connected to the first error correction circuit and the second error correction circuit in parallel, the N-bytes output data connected to the first error correction circuit are separated into a plurality of groups, and the N-bytes output data connected to the second error correction circuit are separated into a plurality of groups.

7. The expanding architecture for error correction code as in claim 6, wherein the plurality of groups of separated N-bytes output data is in successive data byte form.

8. The expanding architecture for error correction code as in claim 6, wherein the plurality of groups of separated N-bytes output data is in non-successive data byte form.

9. A method for expanding error correction code, comprising the steps of:
providing a plurality of data groups from a data end;
providing a plurality of error correction circuits; and
outputting each group of data from the data end to one of the error correction circuit.

10. The method for expanding error correction code as in claim 9, wherein the plurality of data groups is in successive data byte form.

11. The method for expanding error correction code as in claim 9, wherein the plurality of data groups is in non-successive data byte form.

12. The method for expanding error correction code as in claim 9, wherein a portion of the plurality of data groups is in successive data byte form, and a remaining portion of the plurality data groups is in non-successive data byte form.

13. A method for expanding error correction code, comprising the steps of:
providing N-bytes output data from a data end;
providing a first error correction circuit and a second error correction circuit; and
grouping the N-bytes output data and providing the grouped N-bytes output data to the first error correction circuit and the second error correction circuit.

14. The method for expanding error correction code as in claim 13, wherein the grouped N-bytes output data received by the first error correction circuit are in successive data byte form.

15. The method for expanding error correction code as in claim 13, wherein the grouped N-bytes output data received by the second error correction circuit are in non-successive data byte form.
